(19) United States
(12) Patent Application Publication
(10) Pub. No.: US 2022/0376170 A1
(43) Pub. Date: Nov. 24, 2022

(54) MAGNETIC STRUCTURE CAPABLE OF FIELD-FREE SPIN-ORBIT TORQUE SWITCHING AND PRODUCTION METHOD AND USE THEREOF

(71) Applicant: National Taiwan University, Taipei City (TW)

(72) Inventors: Chi-Feng PAI, Taipei City (TW); Tian-Yue CHEN, Taipei City (TW); Wei-Bang LIAO, Taipei City (TW)

(21) Appl. No.: 17/739,966

(22) Filed: May 9, 2022

Related U.S. Application Data
(60) Provisional application No. 63/190,012, filed on May 18, 2021.

(51) Int. Cl. H01L 43/04; H01L 27/22; H01L 43/06; H01L 43/10; H01L 43/14

(52) U.S. Cl. CPC H01L 43/04; H01L 27/222; H01L 43/06; H01L 43/10; H01L 43/14

(57) ABSTRACT

A magnetic structure capable of field-free spin-orbit torque switching includes a spin-orbit coupling base layer and a ferromagnetic layer formed thereon. The spin-orbit coupling base layer is made from a particular crystal material. The ferromagnetic layer has magnetization perpendicular to a plane coupled to the spin-orbit coupling base layer, and is made from a particular ferromagnetic material with perpendicular magnetic anisotropy. The perpendicular magnetization of the ferromagnetic layer is switchable by an in plane current applied to the spin-orbit coupling base layer without application of an external magnetic field. A memory device and a production method regarding the magnetic structure are also provided.

### CROSS-REFERENCE TO RELATED APPLICATION

This application claims priority of U.S. Provisional Patent Application Ser. No. 63/190,012, filed on May 18, 2021.

### FIELD

The disclosure relates to a magnetic structure capable of spin-orbit torque switching and a production method and use thereof, and more particularly to a magnetic structure capable of field-free spin-orbit torque switching and a production method and use thereof.

### BACKGROUND

Spintronics, a portmanteau meaning spin transport electronics (also short for “spin electronics”), refers to not only utilization of electron charges, but also the intrinsic spin of the electrons and the associated magnetic moments. Spintronics can be applied to control, manipulate and measure magnetization of magnetic structures using the spin of an electric current.

Spintronic devices are normally designed based on the following two spin torque effects: spin transfer torque (STT) that refers to the effect by spin polarized charge current in magnetic materials when there is magnetization spatial gradient; and spin orbit torque (SOT) that arises from pure spin currents, with no net charge currents, which are generated by the spin Hall effect, the spin pumping effect, the spin Seebeck effect, magnon transport etc. Furthermore, STT results from the transference of spin angular momentum between two non-collinear magnetic layers or domains, while SOT involves the transfer of spin angular momentum from the SOT source layer to magnetization in adjacent magnetic layer.

Due to its potential applications in ultralow-power memory and logic devices, magnetization switching by current-induced SOT is of great interest. SOT can effectively manipulate magnetization in various types of heterostructures and therefore becomes a strong candidate of writing mechanism for next-generation memory. SOT-based magnetic random access memory (SOT-MRAM) is known for its high storage density, low power consumption, and high retention stability, which makes it potentially more advantageous than STT MRAM.

Memory and logic devices need the SOT effect to switch ferromagnets with perpendicular (out-of-plane) magnetization. However, to utilize current-induced SOT to deterministically drive magnetization switching in magnetic layers with perpendicular magnetic anisotropy (PMA), it is necessary to apply an external magnetic field parallel to the injected current due to the symmetry limitation. The external field majorly breaks the domain wall chiral symmetry and facilitates domain expansion.

Accordingly, there is a need to develop a magnetic structure that can employ SOT to switch perpendicular magnetization without an external magnetic field.

### SUMMARY

A first object of the disclosure is to provide a magnetic structure capable of field-free spin-orbit torque switching, which can alleviate at least one of the drawbacks of the prior art. The magnetic structure includes:
a spin-orbit coupling base layer made from a crystal material selected from the group consisting of a permalloy, a bilayer material of permalloy and platinum, a manganese platinum alloy, an iridium manganese alloy, a platinum-cobalt alloy, a platinum-nickel alloy, a cobalt-nickel-platinum alloy, a face-centered cubic tantalum material, a face-centered cubic tungsten material, a face-centered cubic platinum material, a body-centered cubic molybdenum material, and combinations thereof; and
a ferromagnetic layer formed on the spin-orbit coupling base layer and capable of having magnetization perpendicular to a plane coupled to the spin-orbit coupling base layer, the ferromagnetic layer being made from a ferromagnetic material with perpendicular magnetic anisotropy which is selected from the group consisting of cobalt, cobalt iron boron, a multilayer material of platinum and cobalt, a multilayer of cobalt and nickel, a cobalt-terbium alloy, a cobalt gadolinium alloy, and combinations thereof;
wherein the spin-orbit coupling base layer and the ferromagnetic layer are configured for said magnetization of said ferromagnetic layer to be switchable by an in plane current applied to the spin-orbit coupling base layer without application of an external magnetic field.

A second object of the disclosure is to provide a memory device which can alleviate at least one of the drawbacks of the prior art. The memory device includes the aforesaid magnetic structure.

A third object of the disclosure is to provide a method for producing a magnetic structure capable of field-free spin-orbit torque switching, which can alleviate at least one of the drawbacks of the prior art. The method includes:
forming a spin-orbit coupling base layer from a crystal material selected from the group consisting of a permalloy, a bilayer material of permalloy and platinum, a manganese platinum alloy, an iridium manganese alloy, a platinum-cobalt alloy, a platinum-nickel alloy, a cobalt-nickel-platinum alloy, a face-centered cubic tantalum material, a face-centered cubic tungsten material, a face-centered cubic platinum material, a body-centered cubic molybdenum material, and combinations thereof; and
forming a ferromagnetic layer on the spin-orbit coupling base layer from a ferromagnetic material with perpendicular magnetic anisotropy which is selected from the group consisting of cobalt, cobalt iron boron, a multilayer material of platinum and cobalt, a multilayer material of cobalt and nickel, a cobalt-terbium alloy, a cobalt gadolinium alloy, and combinations thereof, the ferromagnetic layer capable of having magnetization perpendicular to a plane coupled to the spin-orbit coupling base layer;
wherein the spin-orbit coupling base layer and the ferromagnetic layer are configured for the perpendicular magnetization of the ferromagnetic layer to be switchable by an in plane current applied to the spin-orbit coupling base layer without application of an external magnetic field.

### BRIEF DESCRIPTION OF THE DRAWINGS

Other features and advantages of the disclosure will become apparent in the following detailed description of the embodiment(s) with reference to the accompanying drawings, of which:

FIG. 1 is a schematic sectional view illustrating a first embodiment of a magnetic structure capable of field-free spin-orbit torque switching according to the present disclosure;

FIG. 2 is a schematic sectional view illustrating a second embodiment of the magnetic structure capable of field-free spin-orbit torque switching according to the present disclosure;

FIG. 3 is a schematic sectional view illustrating a third embodiment of the magnetic structure capable of field-free spin-orbit torque switching according to the present disclosure;

FIG. 4 is a schematic sectional view illustrating an exemplary magnetic structure capable of field-free spin-orbit torque switching according to the present disclosure, which included, in the following sequence, a thermally-oxidized SiO₂ substrate, a spin-orbit coupling base layer which was a permalloy (Py) layer made of Ni₈₀Fe₂₀, and a ferromagnetic layer having a platinum (Pt) spacer sublayer serving as a spacer, a cobalt (Co) sublayer, and a Pt top sublayer, the exemplary magnetic structure being also referred to as Py(t)/Pt(2)/Co(0.5)/Pt(2), where “t” represents the thickness of the Py layer, and the numbers in the parentheses respectively represent the thicknesses of the sublayers;

FIG. 5 shows structural properties of the exemplary magnetic structure, in which section (a) is a cross-sectional field-emission transmission electron microscope (FE-TEM) image, section (b) shows an X-ray diffraction (XRD) scan result, section (c) is a Py (111) pole figure, and section (d) illustrates breaking of mirror symmetry due to a tilted texture vector;

FIG. 6 shows results of hysteresis loop shift measurement conducted on the exemplary magnetic structure, in which section (a) illustrates the exemplary magnetic structure with a Hall-bar geometry, section (b) shows a representative anomalous Hall (AH) loop of the exemplary magnetic structure (Py(5)/Pt(2)/Co(0.5)/Pt(2)), section (c) shows representative shifted hysteresis loops of the exemplary magnetic structure (Py(5)/Pt(2)/Co(0.5)/Pt(2)) under direct currents (I_{dc}) of 1.6 mA and −1.9 mA, and section (d) shows the current-induced effective field H_{z}^{eff} as a function of I_{dc} under in-plane (IP) fields (Hₓ) of ±500 Oe and 0 Oe, section (e) shows χ (the SOT-induced effective field per current density) as a function of Hₓ for the exemplary magnetic structure (Py(5)/Pt(2)/Co(0.5)/Pt(2)), and section (f) shows the Py thickness dependence of DL-SOT efficiency where the dashed line represents the fitting to a spin diffusion model, V_{H} representing Hall voltage, H_{z} representing out-of-plane (OOP) magnetic field, ξ_{DL} representing IP damping like (DL)-spin-orbit torque (SOT) efficiency, λₛ^{Py} representing the spin diffusion length of the Py layer, t_{py} representing the thickness of the Py layer;

FIG. 7 shows the Hₓ dependence of SOT (spin-orbit torque) switching, in which section (a) illustrates the exemplary magnetic structure with a Hall-bar geometry for current-induced SOT switching measurement, section (b) shows current-induced SOT switching loops for the exemplary magnetic structure (Py(5)/Pt (2)/Co(0.5)/Pt(2)) with applied IP field Hₓ ranging from −20 Oe to 20 Oe, and section (c) shows the critical switching current density (J_{c}) as a function of Hₓ, Iₚᵤₗₛₑ representing pulsed current, Jₚᵤₗₛₑ representing pulsed current density;

FIG. 8 shows magnetization-independent field-free SOT switching, in which sections (a) and (b) respectively illustrate the field-free SOT switching for +Jₚᵤₗₛₑ and −Jₚᵤₗₛₑ after applying +Hₓ, section (c) shows representative field-free SOT switching after applying +Hₓ, sections (d) and (e) respectively illustrate the field-free SOT switching for +Jₚᵤₗₛₑ and −Jₚᵤₗₛₑ after applying −Hₓ, section (f) shows representative field-free SOT switching after applying −Hₓ, m_{Co} representing magnetization state in Co of the Co sublayer, m_{Py} representing magnetization of Py in the Py layer;

FIG. 9 shows field-free SOT switching of current flow along a symmetry-breaking plane (i.e. the x-axis), in which sections (a) and (c) respectively schematically illustrate Jₚᵤₗₛₑ//x, m_{Py}//+y and Jₚᵤₗₛₑ//x, m_{Py}//−y, and sections (b) and (d) respectively show field-free SOT switching loops of Jₚᵤₗₛₑ//x, m_{Py}//+y and Jₚᵤₗₛₑ//x, m_{Py}//−y; and

FIG. 10 shows field-free SOT switching of current flow along a symmetric plane (i.e. the y-axis), in which sections (a) and (c) respectively schematically illustrate Jₚᵤₗₛₑ//y, m_{Py}//±x and Jₚᵤₗₛₑ//y, m_{Py}//±y, and sections (b) and (d) respectively show field-free SOT switching loops of Jₚᵤₗₛₑ//y, m_{Py}//±x and Jₚᵤₗₛₑ//y, m_{Py}//±y.

### DETAILED DESCRIPTION

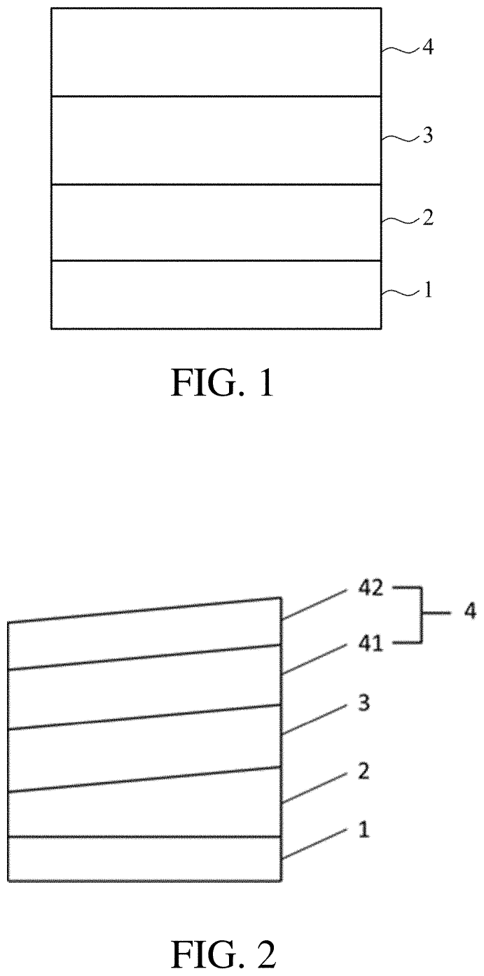

Referring to FIG. 1, a first embodiment of a magnetic structure capable of field-free spin-orbit torque switching according to the present disclosure includes a substrate 1, a spin-orbit coupling base layer 2 formed on the substrate 1, a ferromagnetic layer 3 formed on the spin-orbit coupling base layer 2 opposite to the substrate 1, and a capping layer 4 formed on the ferromagnetic layer 3 opposite to the spin-orbit coupling base layer 2. It should be noted that in other embodiments, the substrate 1 and the capping layer 4 may be dispensed with.

The spin-orbit coupling base layer 2 is able to provide spin orbit torques (SOT) to manipulate the direction of magnetization in the ferromagnetic layer 3. The spin-orbit coupling base layer 2 may be made from a crystal material selected from the group consisting of a permalloy (Py) (e.g. Ni₈₀Fe₂₀), a bilayer material of permalloy and platinum (Py/Pt), a manganese platinum alloy (PtMn), an iridium manganese alloy (IrMn₃), a platinum-cobalt alloy (PtCo), a platinum-nickel alloy (PtNi), a cobalt-nickel-platinum alloy ([CoₓNi₁₋ₓ]Pt, where x ranges from 10 to 35), a face-centered cubic tantalum material (fcc-Ta), a face-centered cubic tungsten material (fcc-W), a face-centered cubic platinum material (fcc-Pt), a body-centered cubic molybdenum material (bcc-Mo), and combinations thereof. The crystal material has a faceted structure.

Since the aforesaid crystal material for the spin-orbit coupling base layer 2 has d orbital and is capable of strong spin-orbit interaction, the spin-orbit coupling base layer 2 can generate spin-orbit torque.

The spin-orbit coupling base layer 2 may be a permalloy layer. The permalloy layer may have a thickness ranging from 3 nm to 10 nm (e.g. 3 nm to 6 nm, 5 nm, etc.).

The spin-orbit coupling base layer 2 may be a buffer layer that is made from the aforesaid crystal material. Alternatively, the spin-orbit coupling base layer 2 may include a seed layer portion that is made from the aforesaid crystal material, and a buffer layer portion that may be made from a common SOT material such as W, Ta, Pt, and so forth.

The ferromagnetic layer 3 is capable of having magnetization perpendicular to a plane coupled to the spin-orbit coupling base layer (i.e. perpendicular magnetization). The ferromagnetic layer may be made from a ferromagnetic material with perpendicular magnetic anisotropy (PMA) which is selected from the group consisting of cobalt, cobalt iron boron, a multilayer of platinum and cobalt (for instance, a Pt/Co/Pt trilayer material, a Pt/Co bilayer material, etc.), a multilayer material of cobalt and nickel (for example, a Co/Ni/Co trilayer material, a Co/Ni bilayer material, etc.), a cobalt-terbium alloy (CoTb), a cobalt gadolinium alloy (CoGd), and combinations thereof.

The spin-orbit coupling base layer 2 and the ferromagnetic layer 3 are configured in a manner that the perpendicular magnetization of the ferromagnetic layer 3 is switchable by an in plane current applied to the spin-orbit coupling base layer 2 without application of an external magnetic field. In other words, when the in plane current is applied to the spin-orbit coupling base layer 2 in the absence of an external magnetic field, the spin-orbit coupling base layer 2 results in SOT, such that the perpendicular (out-of-plane) magnetization of the ferromagnetic layer 3 is triggered (switched).

The ferromagnetic layer 3 may include a platinum spacer sublayer disposed on the spin-orbit coupling base layer 2, a cobalt sublayer disposed on the platinum spacer sublayer opposite to the spin-orbit coupling base layer 2, and a platinum top sublayer disposed on the cobalt sublayer opposite to the platinum spacer sublayer (not shown in FIG. 1, but shown in FIG. 4). The platinum spacer sublayer and the platinum top sublayer may have a thickness ranging from 2 nm to 5 nm (e.g. 2 nm). The cobalt sublayer may have a thickness ranging from 0.5 nm to 2 nm (e.g. 0.5 nm).

The substrate 1 may be made from an amorphous material selected from the group consisting of silicon (Si), silicon oxide (SiO₂), aluminum oxide (Al₂O₃), zirconia (ZrOₓ), titania (TiOₓ), hafnia (HfOₓ), and combinations thereof.

The capping layer 4 may protect and prevent the layers underneath from oxidation, and may promote the magnetic anisotropy in the ferromagnetic layer 3. The capping layer 4 may be made from a material selected from the group consisting of a bilayer material of magnesium oxide and tantalum (MgO/Ta), aluminum oxide (Al₂O₃), silicon oxide (SiO₂), and combinations thereof.

Even though the layers of the magnetic structure of the present disclosure are planar in the first embodiment, it should be noted that there is no particular limitation on the configuration of the layers of the magnetic structure.

Since the magnetic structure of the present disclosure is capable of switching the perpendicular magnetization through SOT without a magnetic field, the present disclosure provides a memory device including such magnetic structure (not shown in the drawings).

A method for producing the first embodiment of the magnetic structure includes the following steps.

The substrate 1 is provided. The spin-orbit coupling base layer 2 is formed on the substrate 1. The ferromagnetic layer 3 is formed on the spin-orbit coupling base layer 2 opposite to the substrate. The capping layer 4 is formed on the ferromagnetic layer 3 opposite to the spin-orbit coupling base layer 2.

The ferromagnetic layer 3 and the spin-orbit coupling base layer 2 may be formed through a deposition process. Examples of the deposition process include, but are not limited to, chemical vapor deposition (such as atmospheric pressure chemical vapor deposition, low-pressure chemical vapor deposition, ultrahigh vacuum chemical vapor deposition, and sub-atmospheric ultrahigh vacuum chemical vapor deposition) and physical vapor deposition (such as cathodic arc deposition, electron-beam physical vapor deposition, evaporative deposition, close-space sublimation, pulsed laser deposition, sputter deposition, pulsed electron deposition). The sputter deposition may be magnetron sputtering, direct current sputtering, radio frequency sputtering, or reactive sputtering.

Referring to FIG. 2, a second embodiment of the magnetic structure capable of field-free spin-orbit torque switching according to the present disclosure is similar to the first embodiment, except for the following differences.

The spin-orbit coupling base layer 2 is made from the face-centered cubic platinum material, and has a wedge configuration. The ferromagnetic layer 3 is made from cobalt, and has an inverted wedge configuration. The capping layer 4 is made from the bilayer material of magnesium oxide (MgO) and tantalum (Ta). Specifically, the capping layer 4 has an MgO sublayer 41 disposed on the ferromagnetic layer 3, and a Ta sublayer 42 disposed on the Mgo sublayer 41 opposite to the ferromagnetic layer 3.

A method for producing the second embodiment of the magnetic structure is similar to the first embodiment of the method, except that the spin-orbit coupling base layer 2 is formed through wedge deposition.

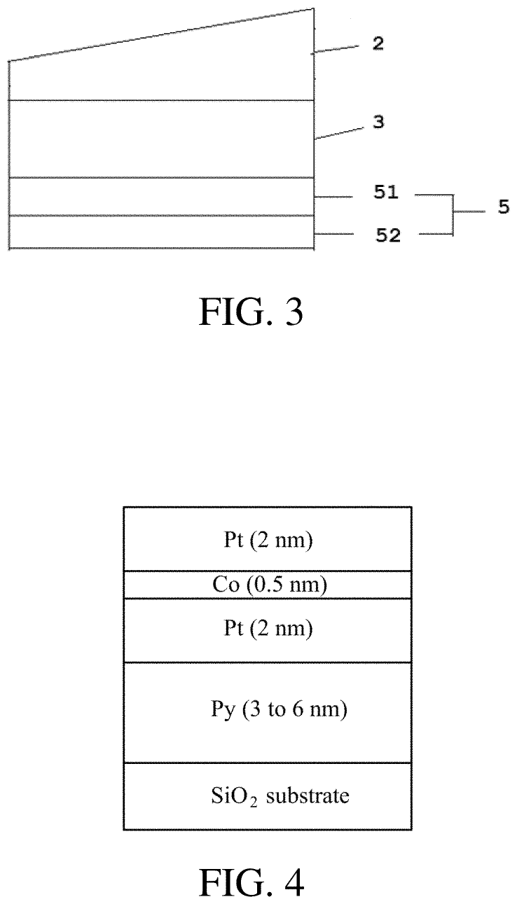

Referring to FIG. 3, a third embodiment of the magnetic structure capable of field-free spin-orbit torque switching according to the present disclosure is similar to the first embodiment, except for the following differences.

The substrate 1 is dispensed with. A seed layer 5 replaces the capping layer 4 and may be made from the same material and in the same manner as the capping layer 4. The layers of the magnetic structure are arranged in an upside-down manner. Namely, the spin-orbit coupling base layer 2 is the uppermost layer, and the seed layer 5 is the lowermost layer.

The spin-orbit coupling base layer 2 is made from the body-centered cubic molybdenum material. The ferromagnetic layer 3 is made from cobalt iron boron. The seed layer 5 is made from the bilayer material of magnesium oxide and tantalum. The spin-orbit coupling base layer 2 has a wedge configuration

The seed layer 5 has an MgO sublayer 51 and a Ta sublayer 52. The Mgo sublayer 51 is disposed between the Ta sublayer 52 and the ferromagnetic layer 3.

A method for producing the third embodiment of the magnetic structure is similar to the first embodiment of the method, except that: the substrate 1 is not provided; the seed layer 5 is formed to replace the capping layer 4; the spin-orbit coupling base layer 2, the ferromagnetic layer 3, and the seed layer 5 are formed in an opposite sequential order; and the spin-orbit coupling base layer 2 is formed through wedge deposition.

The present disclosure will be further described by way of the following examples. However, it should be understood that the following examples are intended solely for the purpose of illustration and should not be construed as limiting the present disclosure in practice.

### Production of Exemplary Magnetic Structure Capable of Field-Free Spin-Orbit Torque Switching According to Present Disclosure

Referring to FIG. 4, an exemplary magnetic structure capable of field-free spin-orbit torque switching according to present disclosure was produced. The exemplary magnetic structure included, in the following sequence, a thermally-oxidized SiO₂ substrate, a spin-orbit coupling base layer which was a permalloy (Py) layer made of Ni₈₀Fe₂₀, and a ferromagnetic layer having a platinum (Pt) spacer sublayer, a cobalt (Co) sublayer, and a Pt top sublayer.

Specifically, the SiO₂ substrate was provided, and the spin-orbit coupling base layer and the ferromagnetic layer were formed through magnetron sputtering using a confocal sputtering system (MEIVAC U.S.A, L200A01) that had six sources for carousel oblique angle deposition and one source for normal incidence deposition. The distance between the SiO₂ substrate and the sputtering target was set to be 20 cm. The base pressure was 3×10⁻⁸ Torr, and all layers of the exemplary magnetic structure were prepared by direct current (dc) sputtering with a working pressure of 3 mTorr.

Regarding the thickness of the components of the exemplary magnetic structure, the Py layer had a thickness ranging from 3 to 6 nm, the Pt spacer sublayer had a thickness of 2 nm, the Co sublayer had a thickness of 0.5 nm, and the Pt top layer had a thickness of 2 nm (the exemplary magnetic structure is also referred to as Py(t)/Pt(2)/Co(0.5)/Pt(2), where “t” represents the thickness of the Py layer, and the numbers in the parentheses respectively represent the thicknesses of the other sublayer/layers). The Py layer and the Co sublayer were respectively deposited from a Ni₈₀Fe₂₀ single target and a Co single target located on the source with an oblique angle of 25°, while the Pt spacer sublayer and the Pt top sublayer was sputtered from the vertical source.

All the components of the exemplary magnetic structure were deposited uniformly onto the SiO₂ substrate by rotating the sample stage at room temperature. The Pt spacer sublayer sandwiched by the Py layer and the Co sublayer was employed to decouple the two ferromagnets (i.e the Py layer and the Co sublayer) and induce interfacial perpendicular magnetic anisotropy (PMA). The Pt top layer served to cancel out the spin current from the Pt spacer sublayer and to prevent the components stacked underneath from oxidizing.

### Property Evaluation for Exemplary Magnetic Structure Capable of Field-Free Spin-Orbit Torque Switching According to Present Disclosure

### Crystal Structure Evaluation

### 1. Evaluation by Field-Emission Transmission Electron Microscopy (FE-TEM)

The exemplary magnetic structure was first subjected to crystal structure evaluation using FEI Tecnai G2 F20. The TEM sample was prepared by a lift-out technique with Helios NanoLab 600i focus ion beam (FIB).

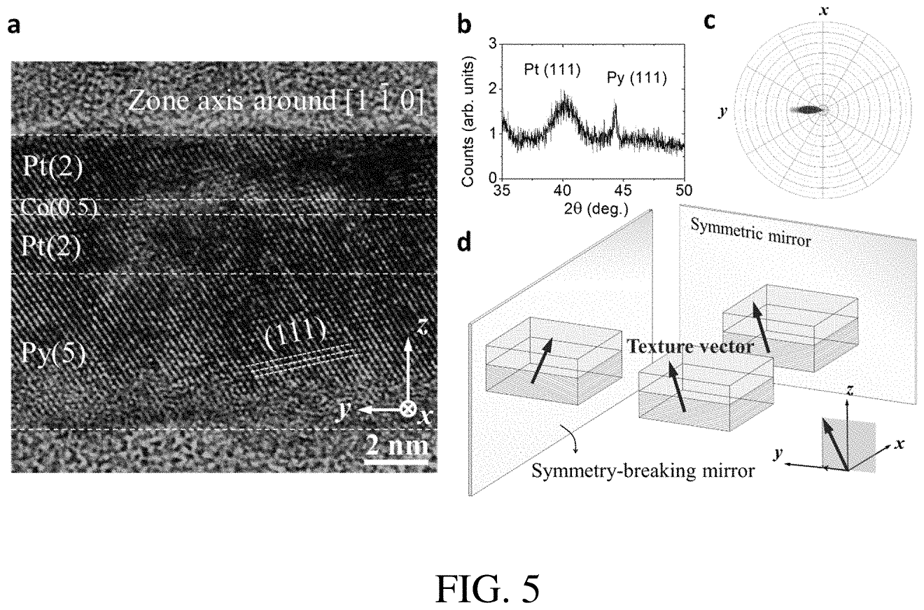

As shown in section (a) of FIG. 5, the cross-sectional TEM image with the view axis close to the zone axis [11̅0] shows an obvious tilted (111) orientation in the exemplary magnetic structure.

### 2. Evaluation by X-Ray Diffraction (XRD)

The exemplary magnetic structure was further subjected to standard θ-2θ scan of XRD using an X-ray diffractometer, Rigaku TTRAX III.

As shown in section (b) of FIG. 5, Py had a naturally strong (111) orientation when deposited on the amorphous SiO2 substrate, and Pt orientated along (111) direction to minimize the lattice mismatch with the Py layer. Furthermore, the XRD pole figure shown in section (c) of FIG. 5 further reveals that Py (111) had a preferred orientation tilted with about 15° in the exemplary magnetic structure, which is consistent with the TEM result above. Lastly, as illustrated in section (d) of FIG. 5, this tilted texture vector therefore produced a symmetry-breaking mirror (along x-z plane) and a symmetric mirror (along y-z plane).

Therefore, the following can be inferred for the exemplary magnetic structure of the present disclosure. Unconventional torques and/or out-of-plane (OOP) spin polarization should exist when the charge current is injected along a symmetry-breaking plane/axis. The tilted texture induced structural asymmetry should allow for the generation of OOP spin polarization as the current is applied along the symmetry-breaking mirror (along the x-axis) of the exemplary magnetic structure. On the contrary, such unconventional spins or spin-orbit torques (SOTs) would completely vanish if the current is applied along the y-axis due to the preserved mirror symmetry.

### Hysteresis Loop Shift Measurement

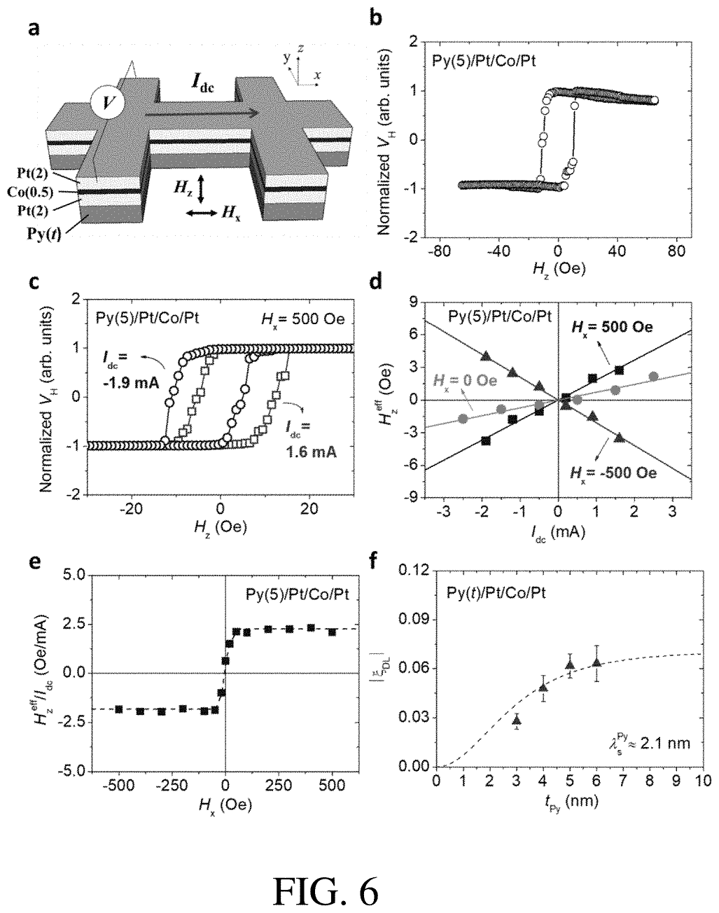

The exemplary magnetic structure was further patterned into a Hall-bar geometry with a lateral dimension of 5 μm×60 μm (i.e. the dimension of the longer bar crossing the two shorter bars) and a dimension of 5 μm×40 μm (i.e. the dimension of the two shorter bars) through a conventional lithography process used in the art (see section (a) of FIG. 6, in which the coordinate system is consistent with that of section (d) of FIG. 5). Since such lithography process is well-known to and commonly used by those skilled in the art, the detail thereof is omitted herein for the sake of brevity. The electrical and spin transport properties of the exemplary magnetic structure were evaluated as follows.

The representative anomalous Hall (AH) loop shown in section (b) of FIG. 6 was obtained by sweeping out-of-plane magnetic field and monitoring the transverse Hall voltage, and indicates the existence of PMA with OOP coercivity of H_{c} of about 10 Oe in the exemplary magnetic structure (i.e. Py(5)/Pt(2)/Co(0.5)/Pt(2)). The interfacial PMA of Pt/Co came from the intermixing of Pt—Co alloy, which agrees with the TEM result. By vibration sample magnetometry (VSM) and anisotropy magnetoresistance (AMR) measurements, it was confirmed that the Co magnetization was normal to the plane without tilting and the in-plane (IP)-magnetized Py had no uniaxial anisotropy (data not shown).

Hysteresis loop shift measurement was performed to determine the current-induced effective field and the damping like (DL)-SOT efficiency from Py. Specifically, a direct current (I_{dc}) was injected into the exemplary magnetic structure along the x-axis (i.e. the symmetry-breaking plane), and an IP field Hx was applied parallel (or antiparallel) to the current while sweeping the OOP magnetic field Hz. The external IP field realigned the domain wall moments and overcame the interfacial Dzyaloshinskii-Moriya interaction (DMI)-induced effective field (H_{DMI}). Once |Hₓ|≥|H_{DMI}|, the domain wall moments aligned along the same direction and the IP DL torque from the SOT source (Py) could fully act on the PMA layer (Co).

Section (c) of FIG. 6 shows the representative loop shifts from the exemplary magnetic structure (i.e. Py(5)/Pt(2)/Co(0.5)/Pt(2)). A positive current-induced effective field H_{z}^{eff} shifted the OOP hysteresis loop from the center to the right under a positive dc current and Hₓ=500 Oe, which suggests a positive spin Hall ratio for Py.

As shown in section (d) of FIG. 6, opposite I_{dc} dependence of effective fields were identified for Hₓ=±500 Oe, which agrees well with the conventional IP DL-SOT scenario. In contrast to conventional cases, there existed a non-zero H_{z}^{eff} even when Hₓ=0 Oe.

Section (e) of FIG. 6 summarizes the SOT strength χ versus Hₓ. χ is defined as the SOT-induced effective field per current density H_{z}^{eff}/J_{dc}=(H_{z}^{eff}/I_{dc})[(ρ_{Pt/Co/Pt}t_{Py}+ρ_{Py}t_{Pt/Co/Pt})/(ρ_{Pt/Co/Pt}t_{Py})], where ρ_{Pt/Co/Pt} represents the resistivity of the PMA composite (i.e. the combination of the Pt spacer sublayer, the Co sublayer, and the Pt top sublayer), and t_{Py} represents the thickness of the Py layer. Note again the existence of a zero-field (Hₓ=0 Oe) effect. The detected effective fields in the exemplary magnetic structure were therefore tentatively attributed to two mechanisms: (1) conventional IP DL-SOT correlated to the classical y-direction spin polarization; and (2) texture-induced torque/effective field correlated to the OOP spin polarization. The effect from the conventional IP torque saturated at χ≈±15 Oe/10¹¹ A·m⁻² (as the DMI was overcome) and the effect from the OOP spin polarization was measured to be χ ≈5.5 Oe/10¹¹ A·m⁻². Note that the observed effects are independent of the magnetization direction of Py, suggesting an intrinsic origin for both IP and OOP spin polarizations.

The apparent IP DL-SOT efficiency (\tilde{ξ}_{DL}) can be further evaluated by the following equation (1):

$${\tilde{ξ}}_{DL} = \frac{2 e}{ℏ} ( \frac{2}{π} ) {μ}_{0} {M}_{s} {t}_{Co}^{eff} {wt}_{Py} χ \qquad ( 1 )$$

where Mₛ is the saturation magnetization (≈1414 emu/cc) of the PMA composite (i.e. the combination of the Pt spacer sublayer, the Co sublayer, and the Pt top sublayer), and w is the Hall-bar width (5 μm). Since the spin current from Py had to transport through the Pt spacer sublayer, the actual DL-SOT efficiency ξ_{DL} of Py is corrected by ξ_{DL}=\tilde{ξ}_{DL}×(sech(t_{Pt}/λₛ^{Pt})⁻¹, where the spin diffusion length of the Pt spacer sublayer (λₛ^{Pt}) was 1.1 nm. Section (f) of FIG. 6 summarizes ξ_{DL} versus the thickness of the Py layer, where the thickness dependence can be well fitted by a spin diffusion model of ξ_{DL}(t_{Py})=ξ_{DL}^{Pt}[1−sech(t_{Py}/λₛ^{Py})] with ξ_{DL}^{Py}≈0.06 and λₛ^{Py}≈2.1 nm. Hence, the conventional IP torque should have a bulk origin (from the spin hall effect (SHE) in Py). It was noted that the symmetric Pt/Co/Pt trilayered composite had little effect on the SOT measurement due to the countering spin currents.

### Evaluation for Current-Induced SOT Switching

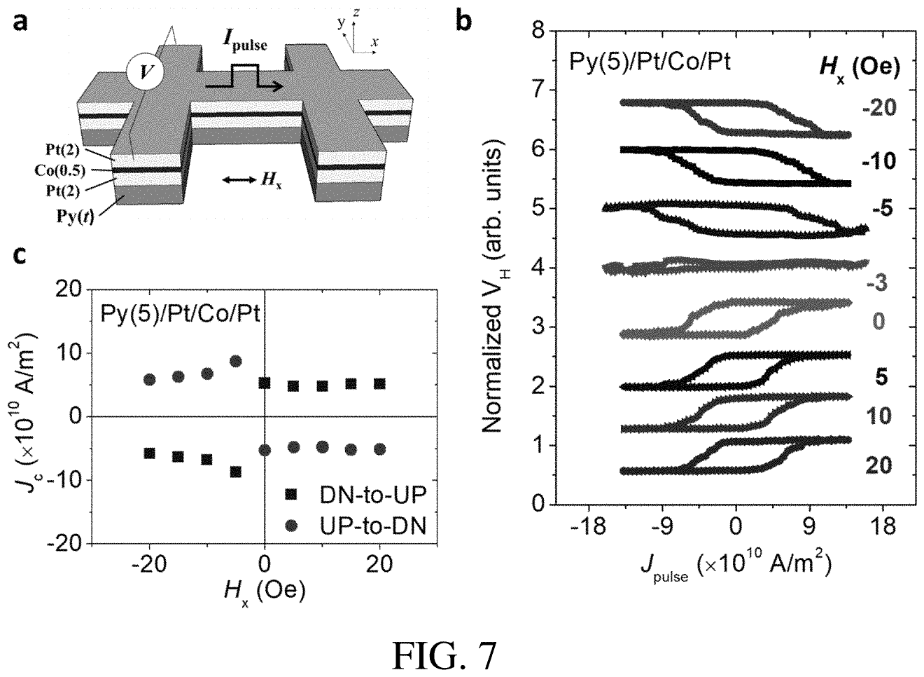

Current-induced SOT switching with various values of Hx was evaluated to verify that the spin current arising from the Py layer could effectively switch the perpendicular magnetization of the Co sublayer. Specifically, a pulsed current with pulse-width tₚᵤₗₛₑ=0.05 s was injected into the exemplary magnetic structure having the Hall-bar geometry while an IP bias field was provided (see section (a) of FIG. 7).

Section (b) of FIG. 7 shows the current-induced SOT switching resulting from the exemplary magnetic structure (i.e. Py(5)/Pt(2)/Co(0.5)/Pt(2)) at various consecutive IP fields, ranging from Hₓ=−20 Oe to Hₓ=20 Oe. The field-assisted SOT switching was driven by IP DL-SOT with y-spin polarization, and the switching polarity is thereby defined by the applied current as well as the applied Hₓ directions, as exactly what was observed at Hₓ=±20 Oe. More importantly, current-induced SOT switching could still be achieved at Hₓ=0 Oe, which is consistent with the existence of an unconventional effective field H_{z}^{eff}/I_{dc} or χ at Hₓ=0 Oe observed in the above-mentioned hysteresis loop shift measurement. The full SOT switching vanished at Hₓ=−3 Oe, which indicates that the compensation of the conventional and the unconventional effective fields.

The critical switching current density (J_{c}) as a function of Hₓ is further summarized in section (c) of FIG. 7. The saturated J_{c}≈5×10¹⁰ A/m² flowing in the Py layer is comparable to those using a 5d transition metal (TM) as a SOT source. Again, the Pt/Co/Pt trilayered composite had little contribution in the SOT switching measurements.

### Evaluation for Magnetization-Independent Field-Free Switching

The non-zero χ and SOT switching in the absence of Hₓ was investigated. For the exemplary magnetic structure with strong texture orientations, it should be symmetry-allowed to gain a z-component in spin polarization when the current is applied along the symmetry-breaking axis (the x-axis). In other words, deterministic switching can be achieved by z-spin polarization (OOP spin polarization) in the absence of Hₓ, in which the switching behavior is solely determined by the applied current direction with respect to the texture vector direction rather than the magnetization of Py.

To verify the aforesaid, genuine field-free switching was performed outside the electromagnet. The magnetization of Py (m_{Py}) in the Py layer was initialized by applying a saturation magnetic field (Hₛₐₜ>1000 Oe) along +x or −x using a permanent magnet, removing the field, and injecting current pulses (tₚᵤₗₛₑ (time of pulse) was 0.05 s). The pulsed current (Iₚᵤₗₛₑ) is swept in the following manner: 0 mA→10 mA→−10 mA→0 mA.

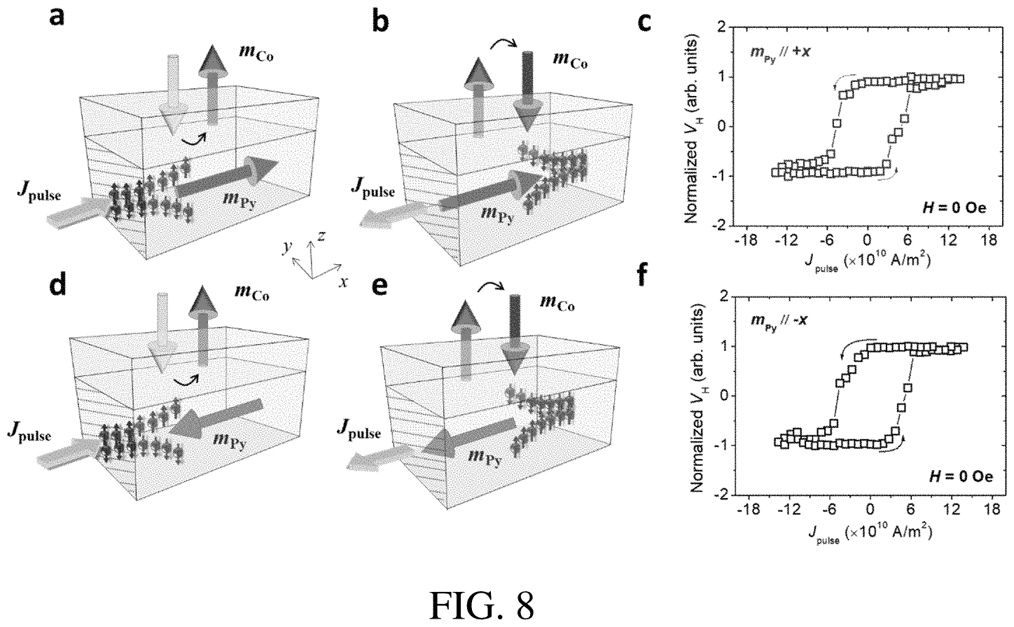

Sections (a) to (c) of FIG. 8 show the illustrations and the result of SOT switching loop with +Hₓ. After applying +Hₓ, the initial magnetization state in Co (m_{Co}) of the Co sublayer was pointing down (−m_{Co}). The +z-spin polarization would switch the −m_{Co} once the critical switching current density is reached. Then +m_{Co} was switched back to a down state when the negative critical switching current density was reached with −z-spin polarization.

The illustrations and result of applying −Hₓ are shown in sections (d) to (f) of FIG. 8. The positive injected current with +z-spin polarization maintained the +m_{Co}. Then the +m_{Co} was switched to −m_{Co} by applying a negative switching current with −z-spin polarization.

In several magnetic systems involving two layers of ferromagnetic materials, the observed field-free SOT switching has been attributed to the interlayer exchange coupling effect, the spin anomalous Hall effect, or the interfacial spin-orbit precession effect produced by the additional IP magnetized ferromagnetic layer. To carefully rule out these possibilities, field-free switching measurement under the following conditions was further conducted: (1) J//x, m_{Py}//+y, (2) J//x, m_{Py}//−y, (3) J//y, m_{Py}//±x, (4) J//y, m_{Py}//±y.

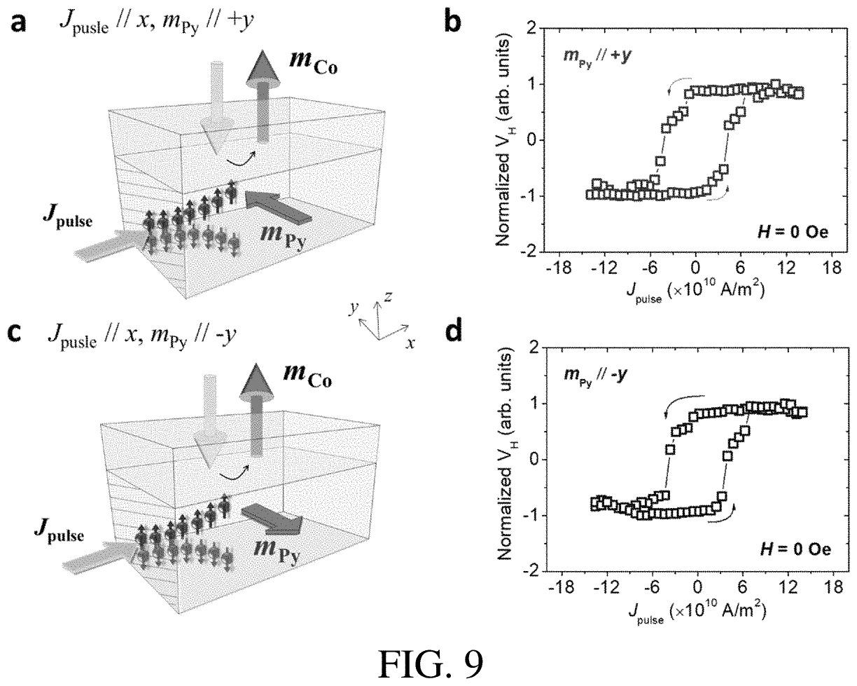

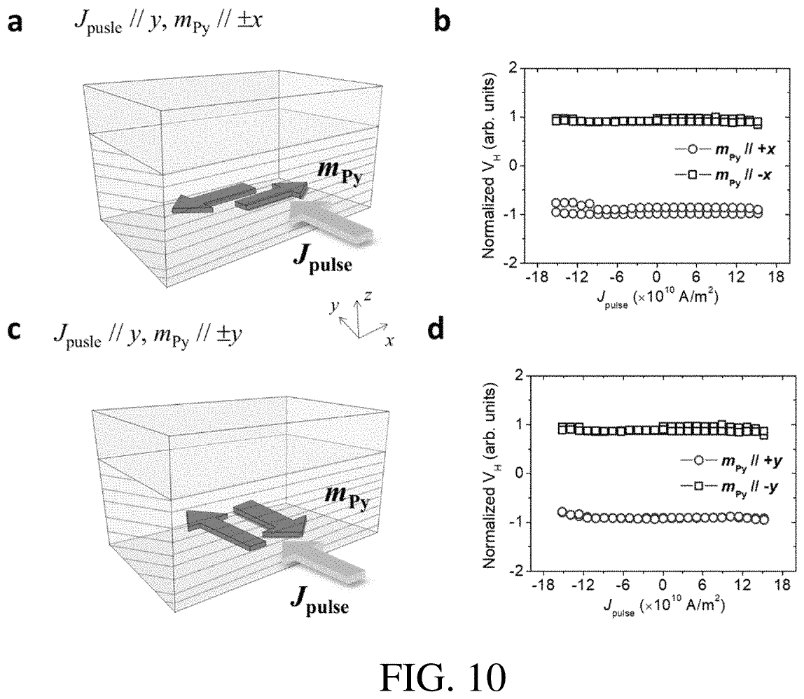

Conditions (1) and (2) are illustrated in sections (a) and (c) of FIG. 9. The current was applied along the symmetry-breaking plane (the x-axis) and the Py magnetization was pre-magnetized along either +y or −y. Again, the same unipolar switching loops as shown in sections (c) and (f) of FIG. 8 were detected, as shown in sections (b) and (d) of FIG. 9. The Py-magnetization-independent unipolar field-free switching behavior can therefore exclude the interlayer exchange coupling effect, the spin anomalous Hall effect, and the interfacial spin-orbit precession effect. These effects should result in a magnetization-dependent bipolar switching loop.

In contrast to conditions (1) and (2), conditions (3) and (4) represent applying currents along the symmetric plane (the y-axis) with the Py magnetization pointing along ±x or ±y, as shown in sections (a) and (C) of FIG. 10. If the field-free switching were governed by the magnetization of Py, the field-free switching should still be observed here. However, no field-free switching could be observed for both conditions, as shown in sections (b) and (d) of FIG. 10.

The above results rule out the possibilities of magnetization-dependent origins for the observed field-free switching, such as the interlayer exchange coupling effect, the spin anomalous Hall effect and the spin-orbit precession effect. Also note that the tilted-magnetization effect of the PMA composite also cannot explain the field-free switching here, since mc, has been checked to be normal to the plane. Robust unipolar field-free SOT switching was observed regardless of the direction of the Py magnetization and solely depended on the current direction, which indicates that the OOP spin polarization-induced SOT can effectively control the magnetization in the PMA composite.

In view of the foregoing, the magnetic structure of the present disclosure can achieve spin orbit switching and out-of-plane (perpendicular) magnetization without an external magnetic field, and hence is applicable to memory and logic devices.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A magnetic structure capable of field-free spin-orbit torque switching, comprising:
a spin-orbit coupling base layer made from a crystal material selected from the group consisting of a permalloy, a bilayer material of permalloy and platinum, a manganese platinum alloy, an iridium manganese alloy, a platinum-cobalt alloy, a platinum-nickel alloy, a cobalt-nickel-platinum alloy, a face-centered cubic tantalum material, a face-centered cubic tungsten material, a face-centered cubic platinum material, a body-centered cubic molybdenum material, and combinations thereof; and
a ferromagnetic layer formed on said spin-orbit coupling base layer and capable of having magnetization perpendicular to a plane coupled to said spin-orbit coupling base layer, said ferromagnetic layer being made from a ferromagnetic material with perpendicular magnetic anisotropy which is selected from the group consisting of cobalt, cobalt iron boron, a multilayer material of platinum and cobalt, a multilayer material of cobalt and nickel, a cobalt-terbium alloy, a cobalt gadolinium alloy, and combinations thereof;
wherein said spin-orbit coupling base layer and said ferromagnetic layer are configured for said perpendicular magnetization of said ferromagnetic layer to be switchable by an in plane current applied to said spin-orbit coupling base layer without application of an external magnetic field.

2. The magnetic structure as claimed in claim 1, wherein said spin-orbit coupling base layer is a permalloy layer.

3. The magnetic structure as claimed in claim 2, wherein said permalloy sublayer has a thickness ranging from 3 nm to 10 nm.

4. The magnetic structure as claimed in claim 1, wherein said ferromagnetic layer includes a platinum spacer sublayer disposed on said spin-orbit coupling base layer, a cobalt sublayer disposed on said platinum spacer sublayer opposite to said spin-orbit coupling base layer, and a platinum top sublayer disposed on said cobalt sublayer opposite to said platinum spacer sublayer.

5. The magnetic structure as claimed in claim 4, wherein each of said platinum spacer sublayer and said platinum top sublayer has a thickness ranging from 2 nm to 5 nm.

6. The magnetic structure as claimed in claim 4, wherein said cobalt sublayer has a thickness ranging from 0.5 nm to 2 nm.

7. The magnetic structure as claimed in claim 1, further comprising a substrate on which said spin-orbit coupling base layer is formed, said ferromagnetic layer being formed on said spin-orbit coupling base layer opposite to said substrate.

8. The magnetic structure as claimed in claim 7, wherein said substrate is made from an amorphous material selected from the group consisting of silicon, silicon oxide, aluminum oxide, zirconia, titania, hafnia, and combinations thereof.

9. The magnetic structure as claimed in claim 1, further comprising a capping layer or a seed layer, when said magnetic structure further comprises said capping layer, said capping layer being formed on said ferromagnetic layer opposite to said spin-orbit coupling base layer, when said magnetic structure further comprises said seed layer, said ferromagnetic layer being formed between said seed layer and said spin-orbit coupling base layer.

10. The magnetic structure as claimed in claim 9, wherein each of said capping layer and said seed layer is made from a material selected from the group consisting of a bilayer material of magnesium oxide and tantalum, aluminum oxide, silicon oxide, and combinations thereof.

11. The magnetic structure as claimed in claim 10, wherein
said spin-orbit coupling base layer is made from a face-centered cubic platinum material or a body-centered cubic molybdenum material,
when said magnetic structure further comprises said capping layer and said spin-orbit coupling base layer is made from said face-centered cubic platinum material, said ferromagnetic layer being made from cobalt, and said spin-orbit coupling base layer having a wedge configuration, and
when said magnetic structure further comprises said seed layer and said spin-orbit coupling base layer is made from said body-centered cubic molybdenum material, said ferromagnetic layer being made from cobalt iron boron, said seed layer being made from the bilayer material of magnesium oxide and tantalum, and said spin-orbit coupling base layer having a wedge configuration.

12. A memory device comprising a magnetic structure as claimed in claim 1.

13. A method for producing a magnetic structure capable of field-free spin-orbit torque switching, comprising:
forming a spin-orbit coupling base layer from a crystal material selected from the group consisting of a permalloy, a bilayer material of permalloy and platinum, a manganese platinum alloy, an iridium manganese alloy, a platinum-cobalt alloy, a platinum-nickel alloy, a cobalt-nickel-platinum alloy, a face-centered cubic tantalum material, a face-centered cubic tungsten material, a face-centered cubic platinum material, a body-centered cubic molybdenum material, and combinations thereof; and
forming a ferromagnetic layer on the spin-orbit coupling base layer from a ferromagnetic material with perpendicular magnetic anisotropy which is selected from the group consisting of cobalt, cobalt iron boron, a multilayer material of platinum and cobalt, a multilayer material of cobalt and nickel, a cobalt-terbium alloy, a cobalt gadolinium alloy, and combinations thereof, the ferromagnetic layer being capable of having magnetization perpendicular to a plane coupled to the spin-orbit coupling base layer;
wherein the spin-orbit coupling base layer and the ferromagnetic layer are configured for the perpendicular magnetization of the ferromagnetic layer to be switchable by an in plane current applied to the spin-orbit coupling base layer without application of an external magnetic field.

14. The method as claimed in claim 13, further comprising providing a substrate before formation of the spin-orbit coupling base layer and the ferromagnetic layer, the spin-orbit coupling base layer being formed on the substrate, the ferromagnetic layer being formed on the spin-orbit coupling base layer opposite to the substrate.

15. The method as claimed in claim 14, wherein the substrate is made from an amorphous material selected from the group consisting of silicon oxide, aluminum oxide, zirconia, titania, hafnia, and combinations thereof.

16. The method as claimed in claim 13, further comprising forming a capping layer or a seed layer, when the capping layer is formed, the capping layer being formed on the ferromagnetic layer opposite to the spin-orbit coupling base layer, when the seed layer is formed, the ferromagnetic layer being formed between the seed layer and the spin-orbit coupling base layer.

17. The method as claimed in claim 16, wherein each of the capping layer and the seed layer is made from a material selected from the group consisting of a multilayer material of magnesium oxide and tantalum, aluminum oxide, silicon oxide, and combinations thereof.

18. The method as claimed in claim 13, wherein the ferromagnetic layer and the spin-orbit coupling base layer are formed through a deposition process.

19. The method as claimed in claim 17, wherein
the spin-orbit coupling base layer is made from a face-centered cubic platinum material or a body-centered cubic molybdenum material,
when the capping layer is formed and the spin-orbit coupling base layer is made from the face-centered cubic platinum material, the ferromagnetic layer being made from cobalt, the capping layer being made from the bilayer material of magnesium oxide and tantalum, and the spin-orbit coupling base layer being formed through wedge deposition, and
when the seed layer is formed and the spin-orbit coupling base layer is made from the body-centered cubic molybdenum material, the ferromagnetic layer being made from cobalt iron boron, the seed layer being made from the bilayer material of magnesium oxide and tantalum, and the spin-orbit coupling base layer being formed through wedge deposition.
